(19) United States
(12) Patent Application Publication
(10) Pub. No.: US 2009/0003041 A1
(43) Pub. Date: Jan. 1, 2009

(54) Semiconductor memory device and read method thereof

(75) Inventor: Kazuhiko Kajigaya, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/213,907

(22) Filed: Jun. 26, 2008

(30) Foreign Application Priority Data
Jun. 27, 2007 (JP) 2007-169808

(51) Int. Cl. G11C 11/56; G11C 11/00; G11C 7/00

(52) U.S. Cl. 365/151; 365/168; 365/189.07

(57) ABSTRACT

A semiconductor memory device comprises a plurality of memory cells each capable of storing at least three different states; a first sense amplifier for amplifying a ternary potential read out in accordance with a state stored in a selected memory cell based on a comparison with a first reference potential; and a second sense amplifier for amplifying a ternary potential read out in accordance with a state stored in the selected memory cell based on a comparison with a second reference potential. In the semiconductor memory device, the ternary potential comprises a high potential, a medium potential and a low potential, the first reference potential is set between the low potential and the medium potential, and the second reference potential is set between the high potential and the medium potential.

### BACKGROUND OF THE INVENTION

1. Field of the Invention

The present invention relates to a semiconductor memory device for storing multiple-valued information, and particularly relates to a semiconductor memory device configured to store ternary data using memory cells capable of storing three different charge states in response to an applied voltage.

2. Description of the related art

A memory cell of a semiconductor memory device is generally formed to store binary information corresponding to “0” and “1”, however research and development of a multiple-valued memory cell capable of storing ternary (or more multiple-valued) information is advanced from a viewpoint of higher integration of the semiconductor memory device. For example, Patent Reference 1 discloses a semiconductor memory device and its reading mechanism, in which there are provided memory cells capable of storing the ternary information by accumulating charge. By employing the configuration and the reading mechanism of the Patent Reference 1, a voltage of a word line is gradually increased with a stepwise waveform and read data can be determined by detecting an output timing of a signal charge from the memory cell. The configuration capable of reading the ternary (or more multiple-valued) information using such a reading mechanism enables to achieve a semiconductor memory device with higher integration.

Patent Reference 1: Japanese Patent Application Laid-open No. S60-13398

However, in the semiconductor memory device of the Patent Reference 1, there is a problem that the time required to confirm read data is not uniform and differs depending on the storage state of the memory cell. Further, since the read operation of the semiconductor memory device does not complete at least until the last data has been confirmed, there is a problem that read time entirely delays. Therefore, it is difficult to achieve both higher integration and fast read operation in the semiconductor memory device.

### BRIEF SUMMARY OF THE INVENTION

An object of the present invention is to provide a semiconductor memory device capable of achieving both higher integration and fast read operation and suppressing an increase in chip area, in which control for confirming read data in a short time is performed using two sense amplifiers with different reference potentials simultaneously when reading a memory cell capable of storing three different charge states.

An aspect of the present invention is semiconductor memory device comprising: a plurality of memory cells each capable of storing at least three different states; a first sense amplifier for amplifying a ternary potential read out in accordance with a state stored in a selected said memory cell based on a comparison with a first reference potential; and a second sense amplifier for amplifying a ternary potential read out in accordance with a state stored in the selected said memory cell based on a comparison with a second reference potential, wherein the ternary potential comprises a high potential, a medium potential and a low potential, the first reference potential is set between the low potential and the medium potential, and the second reference potential is set between the high potential and the medium potential.

According to the semiconductor memory device of the present invention, the ternary potential corresponding to a charge state is read out from the selected memory cell, and compared with the first reference potential in the first sense amplifier while compared with the second reference potential in the second sense amplifier so that the ternary potential is amplified respectively. Then, the first reference potential is set between the low and medium potentials, and the second reference potential is set between the high and medium potentials, thereby reliably determining the ternary potential. In this case, since two sense amplifiers can be operated simultaneously, a time required to confirm read data can be shortened and fast read operation can be achieved with a relatively simple configuration.

In the present invention, each of said memory cells may be a molecule memory cell having a charge state being changed among at least three types due to oxidation-reduction of molecules.

In the present invention, activation and deactivation of said first and second sense amplifiers may be controlled simultaneously in a read operation of said memory cell, and data corresponding to said memory cell may be read out by one amplification operation respectively.

The present invention may further comprises a memory cell array in which said plurality of memory cells are arranged at all intersections of a plurality of word lines and a plurality of bit lines, and said first and second sense amplifiers may amplify the ternary potential which is read out through the bit line from the memory cell selected by activating the word line.

The present invention may further comprises a memory cell array in which said plurality of memory cells are arranged at half intersections of a plurality of word lines and a plurality of bit lines, and said first and second sense amplifiers may amplify the ternary potential which is read out through the bit line connected to the memory cell selected by activating the word line.

The present invention may further comprises a memory cell array in which said plurality of memory cells are arranged at half intersections of a plurality of word lines and a plurality of bit lines, and said first and second sense amplifiers may amplify the ternary potential which is read out through the bit line constituting a complementary pair from the memory cell selected by activating the word line.

In the present invention, each of said first and second sense amplifiers may be connected to one end of the bit line via a switch circuit controlled by a control signal. Further, said first and second sense amplifiers maybe selectively connected to two adjacent bit lines via a first switch circuit controlled by a first control signal and a second switch circuit controlled by a second control signal.

In the present invention, said first and second sense amplifiers may be shared by the two adjacent bit lines.

In the present invention, each of the first and second reference potentials may be directly supplied to said first or second sense amplifier via a transistor. Further, each of the first and second reference potentials may be indirectly supplied to said first or second sense amplifier via a capacitor.

An aspect of the present invention is a read method of a semiconductor memory device having memory cells each capable of storing at least three different states, comprising the steps of: performing a first amplification based on a comparison between a ternary potential read out in accordance with a state stored in a selected said memory cell and a first reference potential; and performing a second amplification based on a comparison between a ternary potential read out in accordance with a state stored in a selected said memory cell and a second reference potential, wherein the ternary potential comprises a high potential, a medium potential and a low potential, the first reference potential is set between the low potential and the medium potential, and the second reference potential is set between the high potential and the medium potential.

In the read method of the present invention, each of said memory cells may be a molecule memory cell having a charge state being changed among at least three types due to oxidation-reduction of molecules. Further, activation and deactivation of the first and second amplifications may be controlled simultaneously, and data corresponding to said memory cell may be read out by one amplification operation respectively.

As described above, according to the semiconductor memory device of the present invention, when reading out the memory cell capable of storing three different states, data is amplified by two sense amplifiers to which different reference potentials are supplied and thus the ternary potential can be reliably determined. In this case, since the read data can be confirmed in one operation by simultaneously operating the two sense amplifiers, an improvement of fast read operation and higher integration can be both achieved. Further, the two sense amplifiers can be shared by two memory cell arrays respectively, and thus a semiconductor memory device with smaller circuit scale and low cost can be achieved.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIGS. 1A and 1B are diagrams explaining structure of a molecule memory cell used in an embodiment;

FIG. 2 is a diagram showing an example of electrical characteristics of the molecule memory cell;

FIG. 3 is a diagram showing an example of a circuit configuration of a ternary memory cell 10 included in a semiconductor memory device;

FIG. 4 is a diagram explaining read operation of the ternary memory cell 10 of FIG. 3;

FIG. 5 is a diagram schematically explaining read method of the ternary memory cell 10 using sense amplifier;

FIGS. 6A, 6B and 6C are diagrams specifically describing a method for determining stored information in the ternary memory cell 10;

FIG. 7 is a diagram for showing a circuit configuration of a first example of the memory cell array and the sense amplifier circuit in the embodiment;

FIG. 8 is a diagram for showing a circuit configuration of a second example of the memory cell array and the sense amplifier circuit in the embodiment;

FIG. 9 is a diagram showing operation waveforms when reading the ternary memory cell 10 storing the state S2 in the first and second examples;

FIG. 10 is a diagram showing operation waveforms when reading the ternary memory cell 10 storing the state S1 in the first and second examples;

FIG. 11 is a diagram showing operation waveforms when reading the ternary memory cell 10 storing the state S0 in the first and second examples;

FIG. 12 is a diagram for showing a circuit configuration of a third example of the memory cell array and the sense amplifier circuit in the embodiment;

FIG. 13 is a diagram showing operation waveforms when reading the ternary memory cell 10 storing the state S2 in the third example;

FIG. 14 is a diagram for showing a circuit configuration of a fourth example of the memory cell array and the sense amplifier circuit in the embodiment;

FIG. 15 is a diagram showing operation waveforms when reading the ternary memory cell 10 storing the state S2 in the fourth example;

FIG. 16 is a diagram for showing a circuit configuration of a fifth example of the memory cell array and the sense amplifier circuit in the embodiment;

FIG. 17 is a diagram showing operation waveforms when reading the ternary memory cell 10 storing the state S2 in the fifth example;

FIG. 18 is a diagram for showing a circuit configuration of a sixth example of the memory cell array and the sense amplifier circuit in the embodiment;

FIG. 19 is a diagram showing operation waveforms of the former half in reading the ternary memory cell 10 storing the state S2 in the sixth example;

FIG. 20 is a diagram showing operation waveforms of the latter half in reading the ternary memory cell 10 storing the state S2 in the sixth example;

FIG. 21 is a diagram for showing a circuit configuration of a seventh example of the memory cell array and the sense amplifier circuit in the embodiment;

FIG. 22 is a diagram showing waveforms when a word line WLi included in a memory cell array MA(B) of FIG. 21 is selected and the ternary memory cell 10 storing the state S2 is read out;

FIG. 23 is a diagram for showing a circuit configuration of an eighth example of the memory cell array and the sense amplifier circuit in the embodiment;

FIG. 24 is a diagram showing operation waveforms when reading the ternary memory cell 10 storing the state S2 in the eighth example;

FIG. 25 is a diagram showing operation waveforms when reading the ternary memory cell 10 storing the state S1 in the eighth example;

FIG. 26 is a diagram showing operation waveforms when reading the ternary memory cell 10 storing the state S0 in the eighth example;

FIG. 27 is a diagram for showing a circuit configuration of a ninth example of the memory cell array and the sense amplifier circuit in the embodiment; and

FIG. 28 is a diagram showing operation waveforms when reading the ternary memory cell 10 storing the state S2 in the ninth example;

### DETAILED DESCRIPTION OF THE INVENTION

A preferred embodiment of the present invention will be described with reference to the accompanying drawings. In this embodiment, the present invention is applied to a semiconductor memory device having molecule memory cells each functioning as a memory cell capable of storing three states of charge density (Hereinafter, this memory cell is referred to as a ternary memory cell).

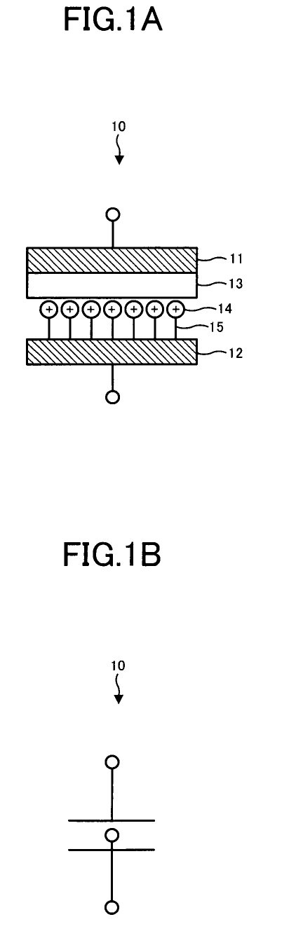

Structure of the molecule memory cell used in the embodiment will be described with reference to FIGS. 1A and 1B. The ternary memory cell 10 shown in FIG. 1A is a molecule memory cell having a solid electrolyte 13, predetermined molecules 14 and a linker 15, all of which are placed between a cathode electrode 11 and an anode electrode 12. For example, molecules having oxidation-reduction characteristics such as porphyrin or ferrocene are used as the molecules 14, and the molecules 14 are electrically connected to the anode electrode 12 via the linker 15. The solid electrolyte 13 allows electric charge to be movable between the cathode electrode 11 and the molecules 14. The ternary memory cell 10 is a two-terminal device having a terminal on the side of the cathode electrode 11 and a terminal on the side of the anode electrode 12, and has a behavior similar to that of a condenser or a battery cell. In addition, FIG. 1B shows circuit symbols of the molecule memory cell having the structure of FIG. 1A.

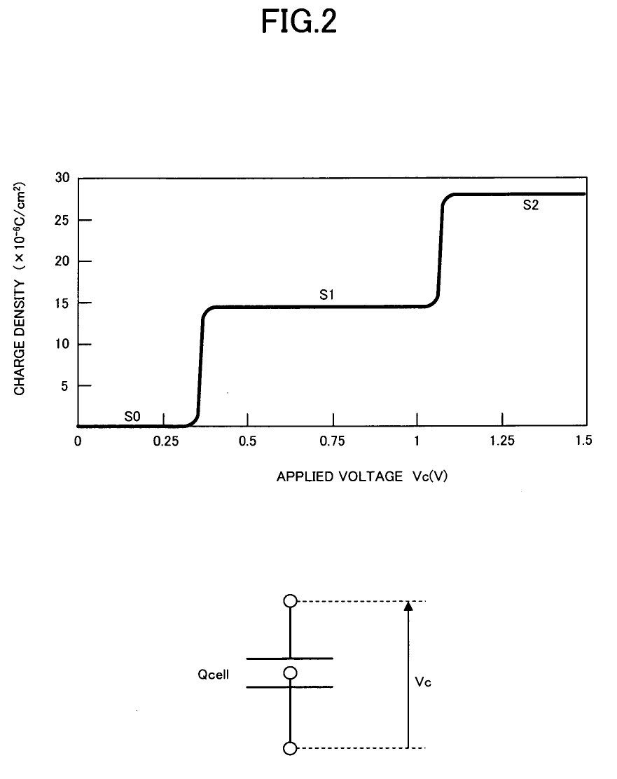

FIG. 2 is a diagram showing an example of electrical characteristics of the above molecule memory cell. The molecule memory cell utilizes an effect that a molecule emits an electron by the oxidation or acquires an electron by the reduction when an electric field is applied to the molecule such as porphyrin or ferrocene. In the molecule memory cell, the state of whether or not the electric charge exists, which has been changed by the oxidation-reduction, continues for a certain time after the electric field is removed. Accordingly, the molecule memory cell operates as the ternary memory cell 10 for storing ternary data by reading whether the molecule memory cell has the electric charge or not.

It is known that the ternary memory cell 10 using some kind of the molecules 14 maintains charge density of three states in response to a voltage applied to both ends thereof. As shown in a graph of FIG. 2, the charge density (charge amount Qcell per unit area) changes in three steps in response to three values into which an applied voltage Vc is divided, in the order of a state S0, a state S1 and a state S2. By reading out these three states S0, S1 and S2 corresponding to “0”, “1” and “2” respectively, the ternary memory cell 10 can be constructed. In this embodiment, a semiconductor memory device with higher integration and lower cost is achieved, which is configured to be capable of reading data from the ternary memory cell 10 in a short time using sense amplifiers, and specific description thereof will be made later.

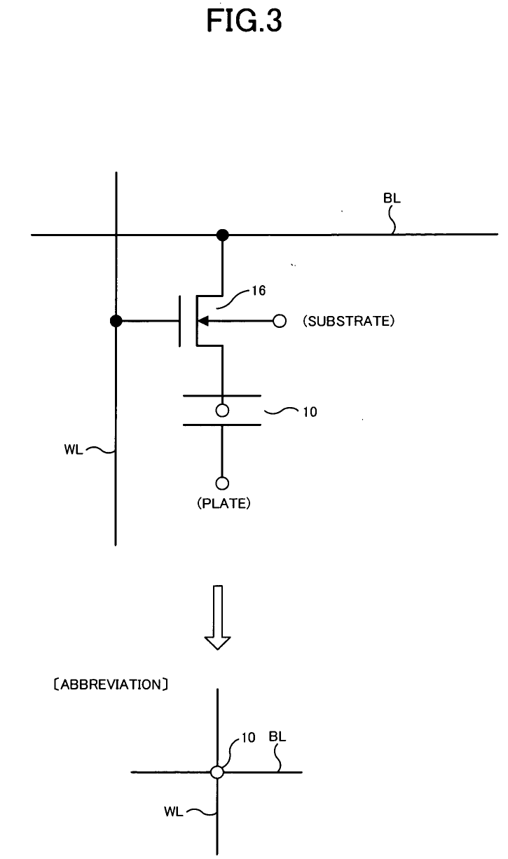

FIG. 3 is a diagram showing an example of a circuit configuration of the ternary memory cell 10 included in the semiconductor memory device. In a memory cell array of the semiconductor memory device, word lines WL and bit lines BL intersecting therewith are arranged, and a series circuit composed of the ternary memory cell 10 and a select transistor 16 is disposed at each intersection. The select transistor 16 is connected between the anode electrode 12 (FIG. 1) of the ternary memory cell 10 and a bit line BL, and the gate thereof is connected to a word line WL. The cathode electrode 11 (FIG. 1) of the ternary memory cell 10 is connected to a plate and a predetermined potential is applied to the cathode electrode 11.

Such a connection relation allows a voltage corresponding to accumulated charge of the ternary memory cell 10 to be read out to the bit line BL via the select transistor 16 when a selected word line WL is activated. By arranging a plurality of word lines WL and a plurality of bit lines BL in the memory cell array, it becomes possible to select and access an arbitrary ternary memory cell 10 from a large number of ternary memory cells 10 arranged in a matrix form. Here, the circuit configuration shown in FIG. 3 will be represented by an abbreviation shown in the lower part of FIG. 3.

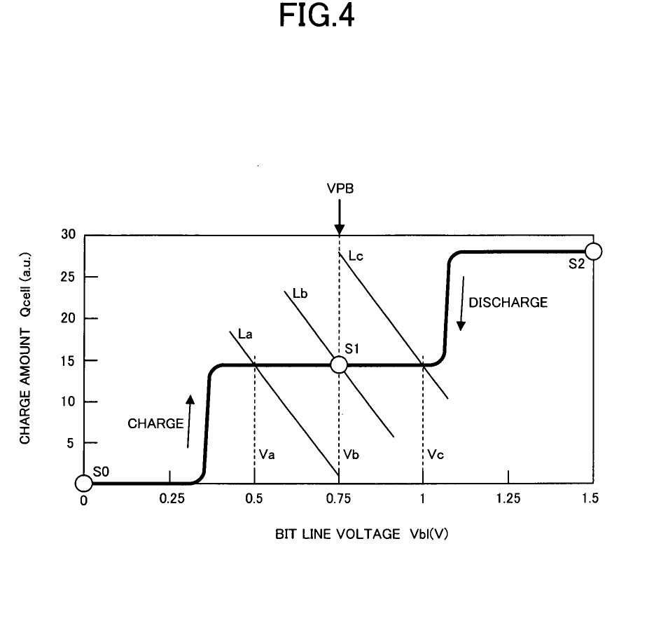

FIG. 4 is a diagram explaining read operation of the ternary memory cell 10 of FIG. 3. In FIG. 4, three bit line load straight lines La, Lb and Lc are shown, in addition to the same graph as in FIG. 2. First, the bit line BL is precharged to a bit line voltage Vbl=0.75V at which the state S1 and the bit line load straight line Lb at the center intersect with each other by a precharge operation preceding the read operation. Note that a bit line precharge voltage VPB (0.75V) is shown in the graph of FIG. 4. In this state, the bit line BL is disconnected from a precharge power supply to be in a floating state while the word line WL is activated to turn on the select transistor 16, so that the potential of the bit line BL changes in response to the charge state of the ternary memory cell 10.

At this point, in a case where the ternary memory cell 10 is in the state SO, the electric charge of the ternary memory cell 10 is charged (oxidized) through the bit line BL based on the left side bit line load straight line La. Thus, the potential of the bit line BL decreases and becomes 0.5V corresponding to a potential Va in FIG. 4. In a case where the ternary memory cell 10 is in the state S1, charge movement between the bit line BL and the ternary memory cell 10 does not occur based on the bit line load straight line Lb at the center. Thus, the potential of the bit line BL maintains 0.75V (a potential Vb in FIG. 4) which is the precharge voltage VPB. In a case where the ternary memory cell 10 is in the state S2, the electric charge is discharged (reduced) to the bit line BL based on the right side bit line load straight line Lc. Thus, the potential of the bit line BL increases and becomes 1V corresponding to a potential Vc in FIG. 4. In this manner, three different potential changes occur in the bit line BL in accordance with the charge amount (ternary information) which has been stored in the ternary memory cell 10, and therefore the information can be read out by amplifying the charge amount by sense amplifiers.

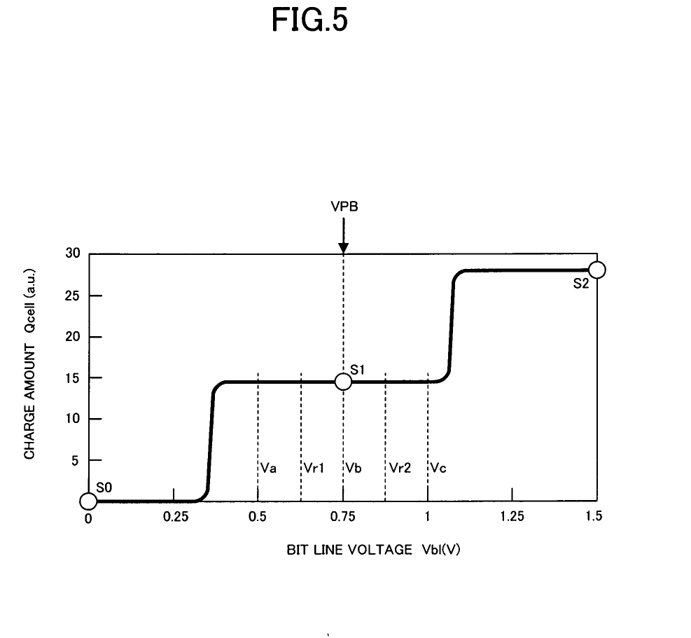

FIG. 5 is a diagram schematically explaining read method of the ternary memory cell 10 using the sense amplifiers. The read method of the ternary memory cell 10 as shown in FIG. 5 can be realized by operating two sense amplifiers simultaneously. In FIG. 5, there are shown a reference potential Vr1 which is an intermediate potential of the potentials Va and Vb, and a reference potential Vr2 which is an intermediate potential of the potentials Vb and Vc, as well as the above potentials Va, Vb and Vc. Further, there are provided a first sense amplifier having one input terminal to which the bit line BL is connected and the other input terminal to which the reference potential Vr1 is connected, and a second sense amplifier having one input terminal to which the bit line BL is connected and the other input terminal to which the reference potential Vr2 is connected, thereby enabling reading out the ternary memory cell 10. In the example of FIG. 5, the reference potential Vr1 is set to 0.625V and the reference potential Vr2 is set to 0.875V. By simultaneously activating the two sense amplifiers having such a connection relation and comparing respective signals amplified by the sense amplifiers, the stored information in the ternary memory cell 10 can be determined.

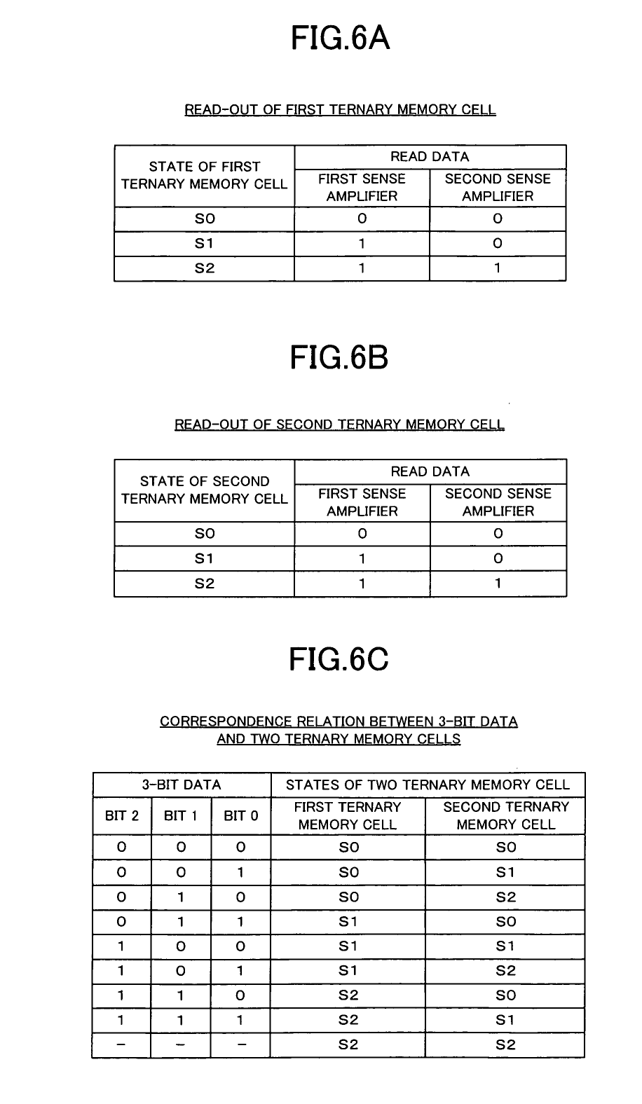

A method for determining the stored information in the ternary memory cell 10 will be specifically described with reference to FIGS. 6A, 6B and 6C. Since the ternary information represented in a binary system corresponds to an information amount of 1.5 bits, it is desirable to associate information of 3 bits with a pair of two ternary memory cells 10. In this case, by simultaneously reading out the two ternary memory cells 10 by two sense amplifiers, a configuration for obtaining all combinations (eight patterns) of the 3-bit binary number can be achieved. FIG. 6A shows a correspondence relation between a first ternary memory cell 10 and read data of the two sense amplifiers, and FIG. 6B shows a correspondence relation between a second ternary memory cell 10 and read data of the two sense amplifiers. As apparent from FIGS. 6A and 6B, relative to the respective states S0, S1 and S2 of the two ternary memory cells 10, the read data of the first sense amplifier changes 0, 1, 1 (binary) and the read data of the second sense amplifier changes 0, 0, 1.

Patterns of the stored information shown in FIG. 6C can be realized based on the correspondence relations shown in FIGS. 6A and 6B. In FIG. 6C, different states of the first and second ternary memory cells 10 are associated with 3-bit binary data represented as bits 0, 1 and 2. There are eight patterns of the 3-bit binary data from 000 to 111, each of which is stored in two ternary memory cells 10 in accordance with different patterns of the states S0, S1 and S2. Thus, by reading out the two ternary memory cells 10 to two bit lines BL and simultaneously activating four sense amplifiers, the 3-bit binary data can be read out in one read operation. Thereby, in this embodiment, since two ternary memory cells 10 are required to be provided in order to store 3-bit data, memory integration can be increased 1.5 times and the semiconductor memory device enabling fast read operation can be realized.

Next, regarding the memory cell array including the ternary memory cell 10 and a sense amplifier circuit in the embodiment, specific configuration and operation will be described. In the following, nine examples for the configuration and operation of the embodiment will be given successively.

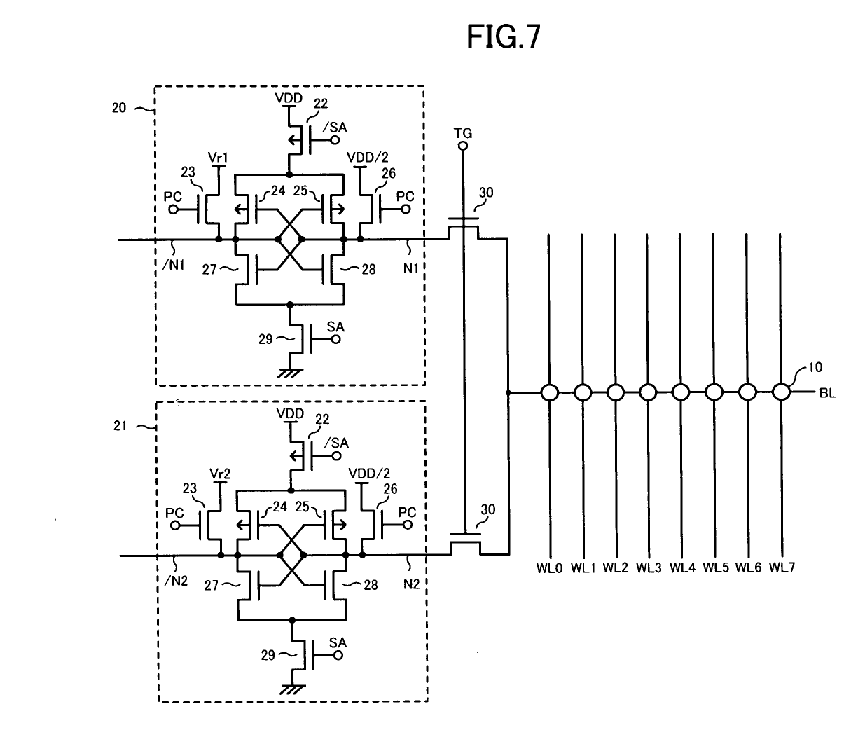

FIG. 7 shows a circuit configuration of a first example of the memory cell array and the sense amplifier circuit in the embodiment. In FIG. 7, there are shown an area including eight word lines WL0 to WL7 and one bit line BL in the memory cell array, a sense amplifier 20 (first sense amplifier), a sense amplifier 21 (second sense amplifier), and two switch transistors 30 connected between the two sense amplifiers 20 and 21 and one ends of the bit lines BL respectively. In the memory cell array, eight ternary memory cells 10 are arranged at intersections of the bit lines BL and the eight word lines WL0 to WL7.

A control signal TG is commonly coupled to gates of the two switch transistors 30. The upper switch transistor 30 controls the connection between the sense amplifier 20 and the bit line BL in response to the control signal TG, and the lower switch transistor 30 controls the connection between the sense amplifier 21 and the bit line BL in response to the control signal TG. Since the control signal TG is common for the two switch transistors 30, either of states is controlled, in one of which the bit line BL is connected to the two sense amplifiers 20 and 21 at the same time, and in the other of which the bit line BL is not connected thereto.

Each of the sense amplifiers 20 and 21 is composed of eight MOS (NMOS or PMOS) transistors 22 to 29. Two PMOS transistors 24, 25 and two NMOS transistors 27, 28 are arranged symmetrically, and the sense amplifiers 20 and 21 are activated by the PMOS transistor 22 on the side of the supply voltage VDD and the NMOS transistor 29 on the ground side. When the sense amplifiers 20 and 21 are activated, a sense amplifier drive signal /SA applied to the gate of the PMOS transistor 22 is controlled to be low and a sense amplifier drive signal SA applied to the gate of the NMOS transistor 29 is controlled to be high. In FIG. 7, there are also shown a pair of nodes N1 and /N1 at both ends of the upper sense amplifier 20, and a pair of nodes N2 and /N2 at both ends of the lower sense amplifier 21, respectively. The node N1 is connected to one switch transistor 30 and the node N2 is connected to the other switch transistor 30. These switch transistors 30 function as the switch circuit of the present invention.

The NMOS transistor 26 connected to one node N1 (N2) precharges the node N1 (N2) with VDD/2 supplied to one end thereof. The NMOS transistor 23 connected to the other node /N1 (/N2) precharges the node /N1 (/N2) with the reference potential Vr1 (Vr2) supplied to the source. A precharge signal PC is applied to gates of NMOS transistors 23 and 26, and a precharge operation is performed when the precharge signal PC is high.

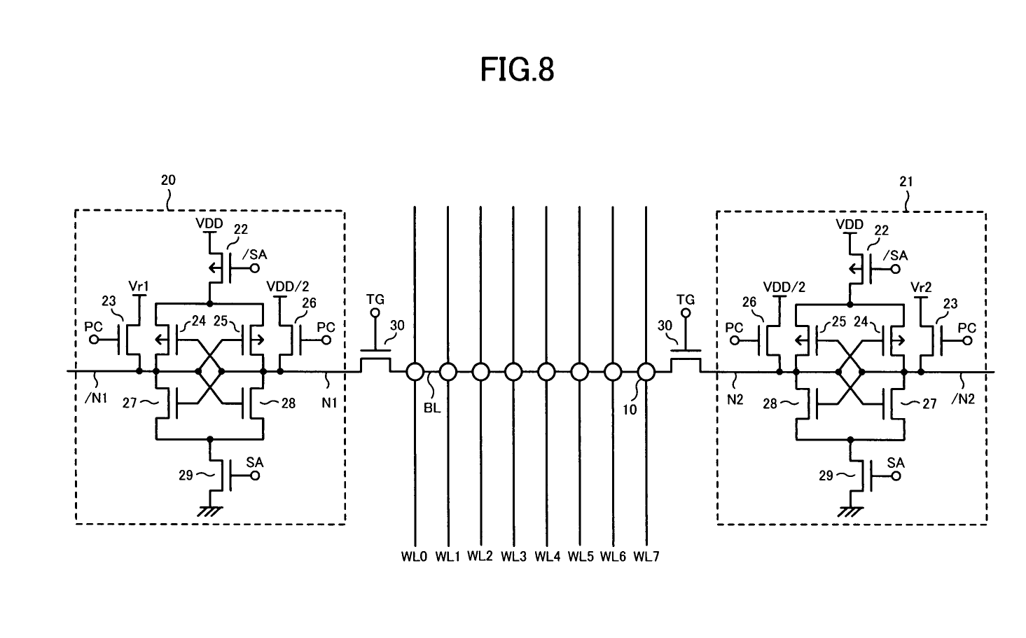

FIG. 8 shows a circuit configuration of a second example of the memory cell array and the sense amplifier circuit in the embodiment. In FIG. 8, there are shown the same area of the memory cell array as in FIG. 7, a sense amplifier 20 (first sense amplifier) and a sense amplifier 21 (second sense amplifier) which are arranged on both sides of the memory cell array, and two switch transistors 30 connected between the two sense amplifiers 20 and 21 and both ends of the bit line BL of the memory cell array, respectively. The left side switch transistor 30 controls the connection between the sense amplifier 20 and the bit line BL in response to the control signal TG, and the right side switch transistor 30 controls the connection between the sense amplifier 21 and the bit line BL in response to the control signal TG. In this manner, FIG. 8 in which the two sense amplifiers 20 and 21 are arranged on left and right sides differs from FIG. 7 in which they are arranged on upper and lower sides. The feature of FIG. 8 is that the sense amplifiers 20 and 21 can be arranged in accordance with the pitch of the bit lines BL.

The circuit configuration of the sense amplifiers 20 and 21 is almost common to that of FIG. 7. However, the left side sense amplifier 20 and the right side sense amplifier 21 are symmetrically arranged with respect to the memory cell array at the center, and nodes N1, N2 are arranged on the inside while nodes /N1, /N2 are arranged on the outside. In this case, it is the same as in FIG. 7 in that one node N1 (N2) is precharged to VDD/2 and the other node /N1 (/N2) is precharged to the reference potential Vr1 (Vr2).

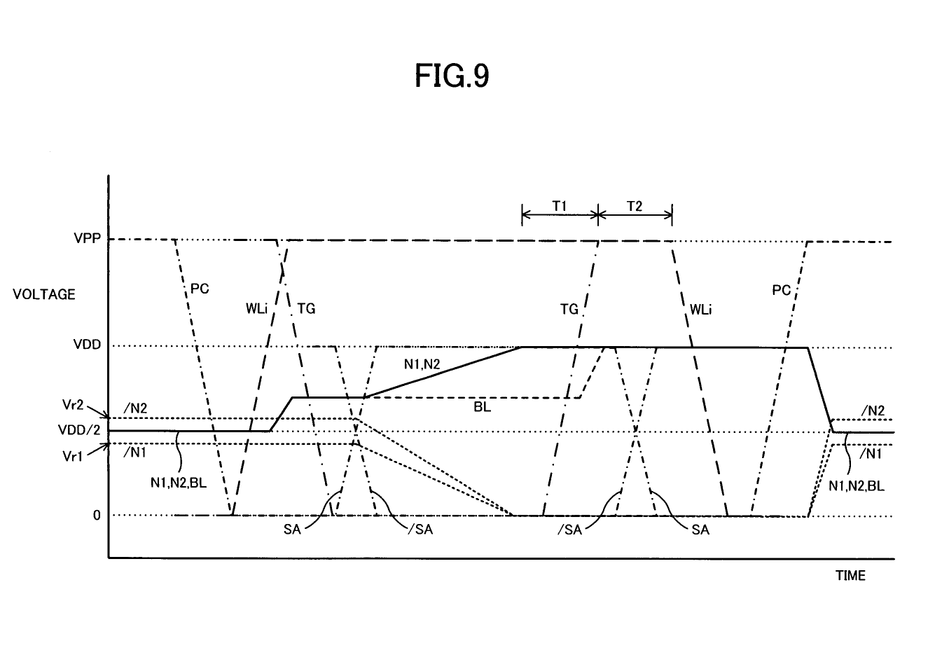

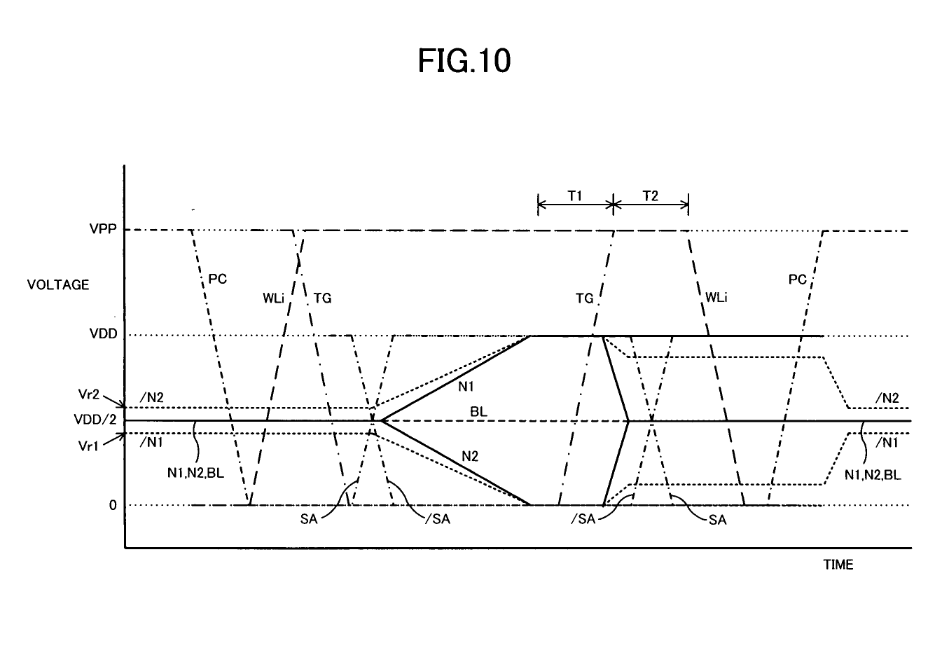

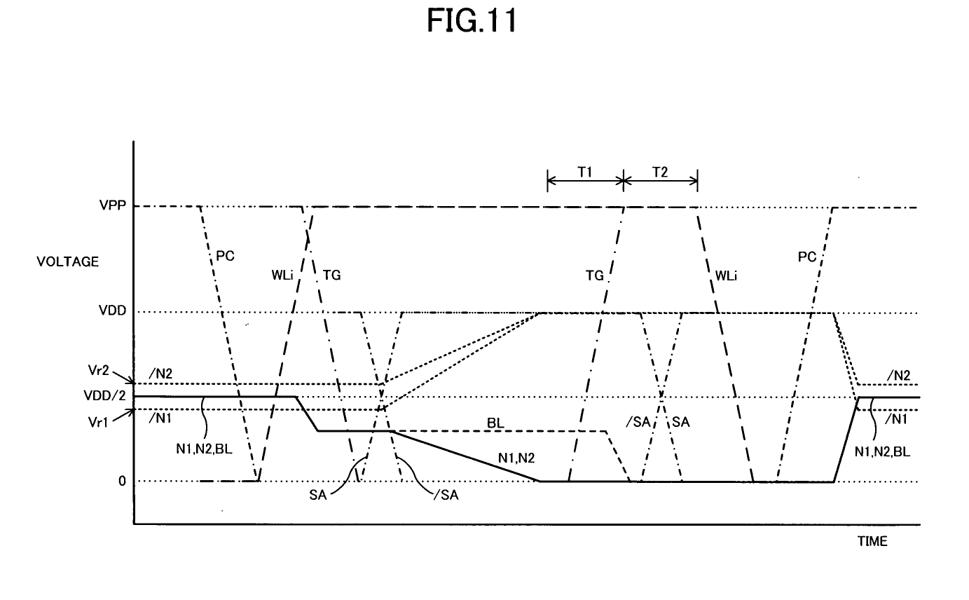

Next, operations in cases of using circuit configurations of the first example of FIG. 7 and the second example of FIG. 8 will be described. FIGS. 9 to 11 show operation waveforms common to the circuit configurations of the first and second examples, which correspond to operations of storing the state S2 (FIG. 9), the state S1 (FIG. 10) and the state S0 (FIG. 11) respectively in the ternary memory cell 10.

First, the operation when reading the state S2 will be described with reference to FIG. 9. The precharge signal PC is maintained high (voltage VPP) during an initial precharge period. Thus, in the respective sense amplifiers 20 and 21, the nodes N1 and N2 are precharged to VDD/2, the nodes /N1 is precharged to the reference potential Vr1, and the node /N2 is precharged to the reference potential Vr2. Further, the control signal TG is maintained high (voltage VPP) during the precharge period, the bit line BL is in a state of being connected to the two nodes N1 and N2. When the precharge signal PC is controlled to be low during a read access to an arbitrary ternary memory cell 10, the precharge is cancelled so that the bit line BL becomes in a floating state. Subsequently, when the selected word line WLi rises to the voltage VPP, the potential of the bit line BL increases from VDD/2 in response to the state S2 of a selected ternary memory cell 10. Simultaneously, potentials of the nodes N1 and N2 increase as well as the bit line BL.

At this point, the control signal TG changes from high to low, and the bit line BL is disconnected from the two sense amplifiers 20 and 21. Thereafter, operations of the sense amplifiers 20 and 21 starts by controlling the sense amplifier drive signals SA and /SA. In the sense amplifiers 20 and 21, one nodes N1 and N2 are maintained at the potential of the bit line BL while the other nodes /N1 and /N2 are maintained at the reference potentials Vr1 and Vr2 of the same level as the precharge. As shown in FIG. 9, the reference potential Vr1 is slightly lower than VDD/2, and the reference potential Vr2 is slightly higher than VDD/2. Thus, the potential of the bit line BL at this point is higher than both the reference potentials Vr1 and Vr2, and therefore the nodes N1 and N2 are amplified to high (supply voltage VDD) by the operations of the sense amplifiers 20 and 21. During a read period T1 of FIG. 9, signals amplified by the sense amplifiers 20 and 21 are read out to outside by a read circuit (not shown). Thereby, one read operation completes.

In the embodiment, since a so-called destructive read-out is performed for the ternary memory cell 10 as the molecule memory cell, read information needs to be written back to the ternary memory cell 10. Thus, the control signal TG is controlled to be high, and a rewrite operation is performed during a rewrite period T2 of FIG. 9. That is, since the bit line BL is connected to the nodes N1 and N2 of the sense amplifiers 20 and 21, the bit line BL is pulled up to the high potential of the nodes N1 and N2, thereby the state S2 is written back to the original ternary memory cell 10. Thereafter, operations of the sense amplifiers 20 and 21 are deactivated by controlling the sense amplifier drive signals SA and /SA, and the rewrite operation completes by lowering the potential of the word line WL to low. Subsequently, the precharge signal PC is controlled to be high, and the nodes N1, N2, /N1, /N2 and the bit line BL are respectively precharged.

Next, the operation when reading the state S1 will be described with reference to FIG. 10. Many operation waveforms in FIG. 10 are common to those in FIG. 9, so different points will be mainly described below. As shown in FIG. 10, after the initial precharge operation, when reading out the ternary memory cell 10 storing the state S1 to the bit line BL, the potential of the bit line BL does not change and the state of VDD/2 is maintained. Here, the potential of the node /N1 is lower than that of the bit line BL, and the potential of the node /N2 is higher than that of the bit line BL. Therefore, when the sense amplifiers 20 and 21 are activated by controlling the sense amplifier drive signals SA and /SA, determination results of the bit line BL in the sense amplifiers 20 and 21 are reverse to each other. Accordingly, the node N1 of the sense amplifier 20 is amplified to high, and the node N2 of the sense amplifier 21 is amplified to low. The amplified signals are read out to outside by the read circuit (not shown) during the read period T1, and thereby one read operation completes.

Thereafter, since the node N1 of high and the node N2 of low are shorted at one end of the bit line BL when the control signal TG is controlled to be high, an intermediate potential VDD/2 is generated. Immediately thereafter, when operations of the sense amplifiers 20 and 21 are deactivated by controlling the sense amplifier drive signals SA and /SA, it can be prevented that a through current flows in the sense amplifiers 20 and 21. During the rewrite period T2, the potential of the bit line BL, which has been driven to VDD/2, is written back to the original ternary memory cell 10 as the state S1, and subsequently the precharge operation is performed in the same manner as in FIG. 9.

Next, the operation when reading the state S0 will be described with reference to FIG. 11. Many operation waveforms in FIG. 11 are common to those in FIGS. 9 and 10, so different points will be mainly described below. It is understood that changes in operation waveforms of the bit line BL and the nodes N1, N2 /N1 and /N2 are reverse to those in FIG. 9. That is, when the selected word line WLi is activated, the potential of the bit line BL and the potentials of the nodes N1 and N2 are lowered from VDD/2 in response to the state S0 of a selected ternary memory cell 10. Thereafter, when the sense amplifiers 20 and 21 are activated with the control signal TG in a state of being low, the nodes N1 and N2 are amplified to low by operations of the sense amplifiers 20 and 21, since the other nodes /N1 and /N2 being maintained at the reference potentials Vr1 and Vr2 are higher than one nodes N1 and N2 being maintained at the potential of the bit line BL. During the read period T1 of FIG. 9, signals amplified by the sense amplifiers 20 and 21 are read out to outside by the read circuit (not shown), and thereby one read operation completes.

Thereafter, since the bit line BL is connected to the nodes N1 and N2 of the sense amplifiers 20 and 21 when the control signal TG is controlled to be high, the bit line BL is lowered to the low potential of the nodes N1 and N2. During the rewrite period T2, the potential of the bit line BL, which has been driven to low, is written back to the original ternary memory cell 10 as the state S0, and subsequently the precharge operation is performed in the same manner as in FIG. 9.

As described above, by employing the first or second example, activation and deactivation of the two sense amplifiers 20 and 21 are controlled simultaneously, regardless of whichever the two ternary memory cells 10 stores the state S0, S1 or S2, and read data can be confirmed in one cycle. Thus, it can be prevented that read speed of the data is delayed depending on the state of the ternary memory cell 10, and uniform and fast read operation can be achieved. Note that the effect regarding the fast read operation is not limited to the first and second examples but is common to all examples which will be described in the following.

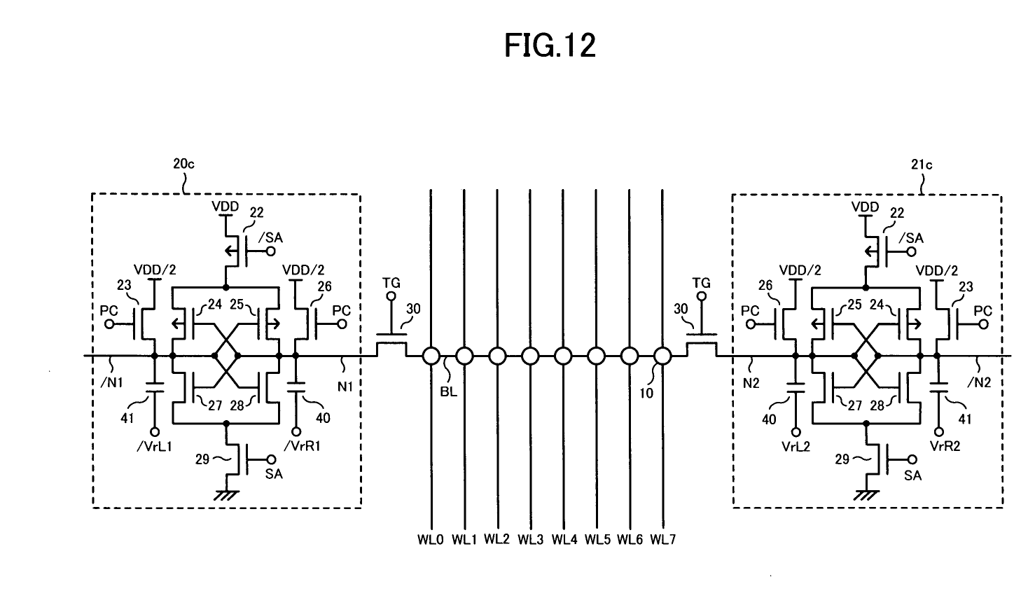

Next, FIG. 12 shows a circuit configuration of a third example of the memory cell array and the sense amplifier circuit in the embodiment. The circuit configuration of FIG. 12 is almost common to that of the first and second examples (FIGS. 7 and 8), however differences exist in portions related to precharging the nodes N1 and /N1 of the sense amplifier 20c and the nodes N2 and /N2 of the sense amplifier 21c. Specifically, VDD/2 is supplied to the source of the NMOS transistor 23, a capacitor 40 is connected to the node N1 (N2), and a capacitor 41 is connected to the node /N1 (/N2), which differ from FIG. 8. In the left side sense amplifier 20c, reference potential applying signals /VrR1 and /VrL1 are applied to opposite electrodes of the capacitors 40 and 41 respectively. In the right side sense amplifier 21c, reference potential applying signals VrL2 and VrR2 are applied to opposite electrodes of the capacitors 40 and 41 respectively.

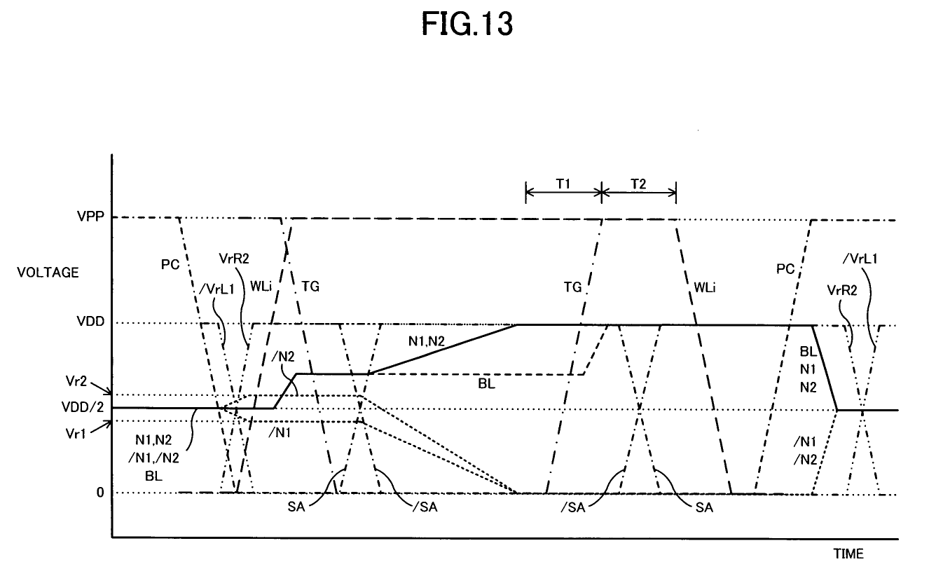

The operation when reading from the ternary memory cell 10 storing the state S2 in the third example will be described with reference to FIG. 13. During the initial precharge period, the precharge signal PC is maintained high and all the nodes N1 /N1, N2 and /N2 are precharged to VDD/2. At this point, the bit line BL is also precharged to VDD/2 since the control signal TG is maintained high. After the precharge period, the reference potential applying signal /VrL1 is driven from high to low and the reference potential applying signal VrR2 is driven from low to high, respectively before the selected word line WLi rises. Capacitances of the capacitors 41 of two sense amplifiers 20c and 21c are adjusted to predetermined values by these signals, and the reference potential Vr1 is generated at the node /N1 while the reference potential Vr2 is generated at the node /N2.

Subsequent operation is performed in the same manner as in FIG. 9 until the read and rewrite operations complete, so description thereof will be omitted. Meanwhile, when the precharge signal goes high during the last precharge period, the nodes N1, /N1, N2, /N2 and the bit line BL are all precharged to VDD/2 in the same manner as the initial precharge period. Subsequently, the reference potential applying signal /VrL1 is driven from low to high and the reference potential applying signal VrR2 is driven from high to low, thereby returning to the first state. Although a case has been representatively described where the ternary memory cell 10 stores the state S2 in FIG. 13, other states S1 and S0 follow the similar operation, in which only some waveforms are different (see FIGS. 10 and 11 corresponding to FIG. 9), so description thereof will be omitted.

As shown in the operation waveforms of FIG. 13, the reference potential applying signals /VrR1 and VrL2 on the sides of the nodes N1 and N2 are not activated. This is because that the capacitors 40 of FIG. 12 are provided for the purpose of making equal the capacitances between the nodes N1 and /N1 (N2 and /N2) at both ends of the sense amplifier 20c (21c).

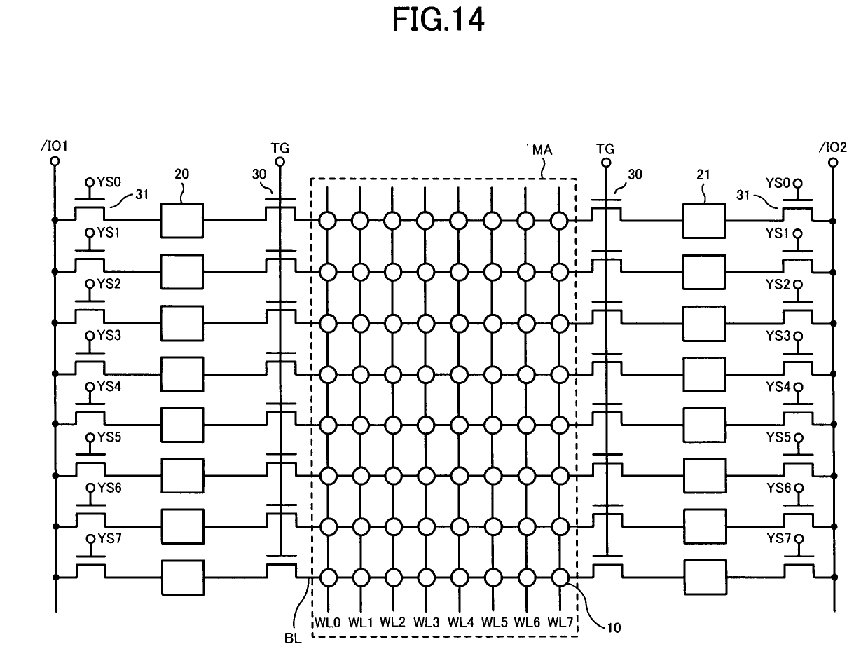

Next, FIG. 14 shows a circuit configuration of a fourth example of the memory cell array and the sense amplifier circuit in the embodiment. In the fourth example, there is provided a memory cell array MA in which the circuit configuration of the second example (FIG. 8) is used as a basic unit and arranged in an array form. In the memory cell array MA, ternary memory cells 10 are arranged at all intersections of bit lines BL and word lines WL0 to WL7. The switch transistor 30, the sense amplifiers 20, 21 and a MOS transistor 31 are connected in series at each side of each bit line BL in the memory cell array MA. The switch transistor 30 and the sense amplifiers 20 and 21 are configured in the same manner as in FIG. 8.

Meanwhile, the MOS transistors 31 controls connections between common input/output lines /IO1 and /IO2 and the sense amplifiers 20 and 21 in response to select signals YS0 to YS7 applied to the gates. These select signals YS0 to YS7 are supplied to a pair of the sense amplifiers 20 and 21 individually on the both sides of the memory cell array MA. The amplified signal from the left side sense amplifier 20 is read out through one input/output line /IO1 and the amplified signal from the right side sense amplifier 21 is read out through the other input/output line /IO2, respectively, when selected by the select signals YS0 to YS7.

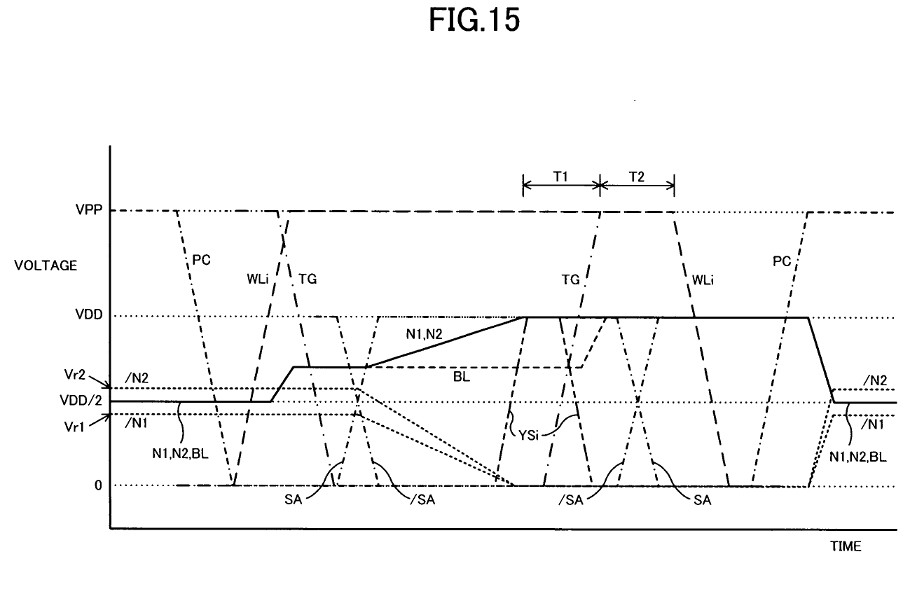

The operation when reading from the ternary memory cell 10 storing the state S2 in the fourth example will be described with reference to FIG. 15. Many operation waveforms in FIG. 15 are common to those in FIG. 9, so different points will be mainly described below. In FIG. 15, the nodes N1 and N2 are amplified to high while the nodes /N1 and /N2 are amplified to low by the sense amplifiers 20 and 21, and thereafter a predetermined select signal YSi changes from low to high. Thereby, low potential of the nodes /N1 and /N2 are read out to the input/output lines /IO1 and /IO2 (not shown in FIG. 15) via the MOS transistor 31.

By employing the above fourth example, the ternary memory cells 10 can be arranged at all intersections in the memory cell array MA, and thus integration of the semiconductor memory device can be improved in addition to the fast read operation.

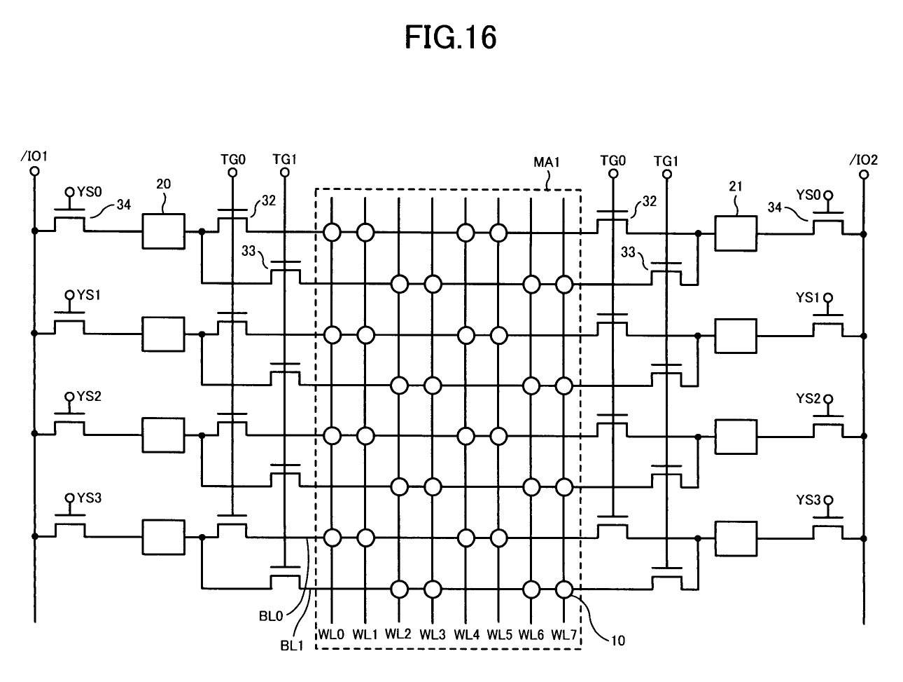

Next, FIG. 16 shows a circuit configuration of a fifth example of the memory cell array and the sense amplifier circuit in the embodiment. In the fifth example, there is provided a memory cell array MA1 in which the circuit configuration of the second example (FIG. 8) is used as the basic unit, however the arrangement of the memory cell array MA1 differs from that of the fourth example. That is, ternary memory cells 10 are arranged at half intersections of the bit lines BL and the word lines WL0 to WL7. Two adjacent bit line BL0 and BL1 form a pair and share the sense amplifiers 20 and 21 on both sides, and there are provided switch transistors 32 for controlling connections between the one bit line BL0 and the sense amplifiers 20 and 21, and switch transistors 33 for controlling connections between the other bit line BL1 and the sense amplifiers 20 and 21. A control signal TG0 is applied to the gate of the switch transistor 32, and a control signal TG1 is applied to the gate of the switch transistor 33, both of which are controlled individually.

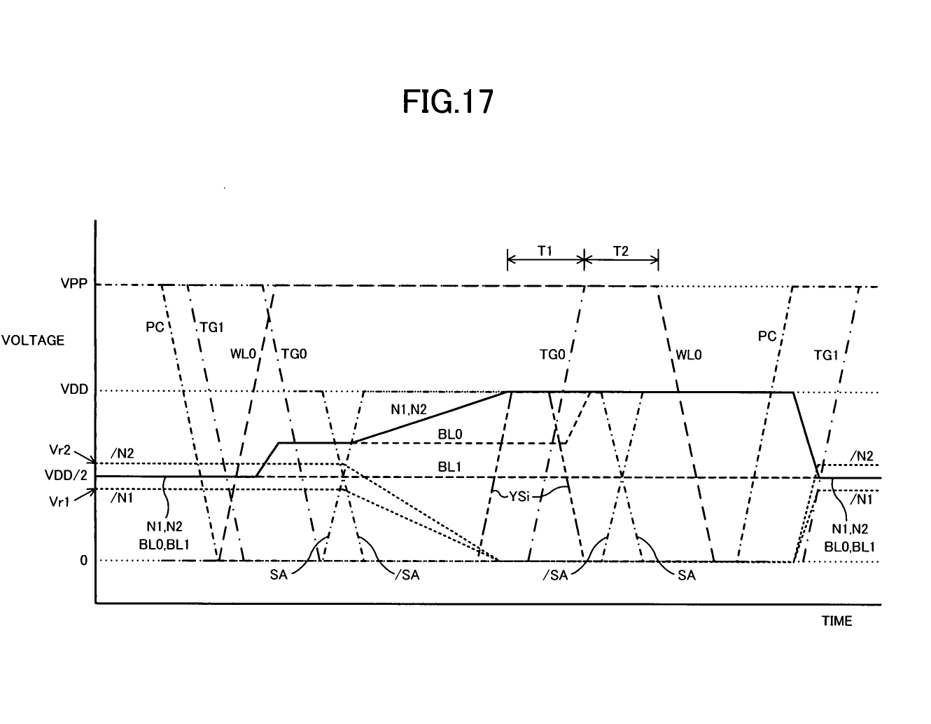

The operation when reading from the ternary memory cell 10 storing the state S2 in the fifth example will be described with reference to FIG. 17. Many operation waveforms in FIG. 17 are common to those in FIG. 15, so different points will be mainly described below. Since the ternary memory cells 10 are arranged in two patterns for each word line WL in the configuration of FIG. 16, a state is assumed in which the word line WL0 at the left end is selected. The ternary memory cell 10 storing the state S2 on the side of the bit line BL0 needs to be selected corresponding to the selected word line WL0. Thus, the control signal TG1 corresponding to the bit line BL1 is controlled to be low, and the bit line BL1 is disconnected from sense amplifiers 20 and 21 on the both sides. Thereafter, the selected word line WL0 is activated, and data of the ternary memory cells 10 are amplified by the sense amplifiers 20 and 21 through the bit line BL0. Subsequently, after the same operation as in FIG. 15 is performed, the control signal TG0 returns to high. Then, control is performed so that the selected word line WL0 falls, the precharge signal PC goes high, and finally the control signal TG1 returns to high, in this order.

By employing the above fifth example, the ternary memory cells 10 can be arranged at half intersections in the memory cell array MA, and read-out of each bit line BL to which the selected ternary memory cell 10 is connected can be performed. Therefore, it is possible to loosen the arrangement pitch of the sense amplifiers in addition to the fast read operation. Further, since the adjacent non-selected bit line BL1 serves as a shield, a configuration advantageous for improving a sense margin can be achieved.

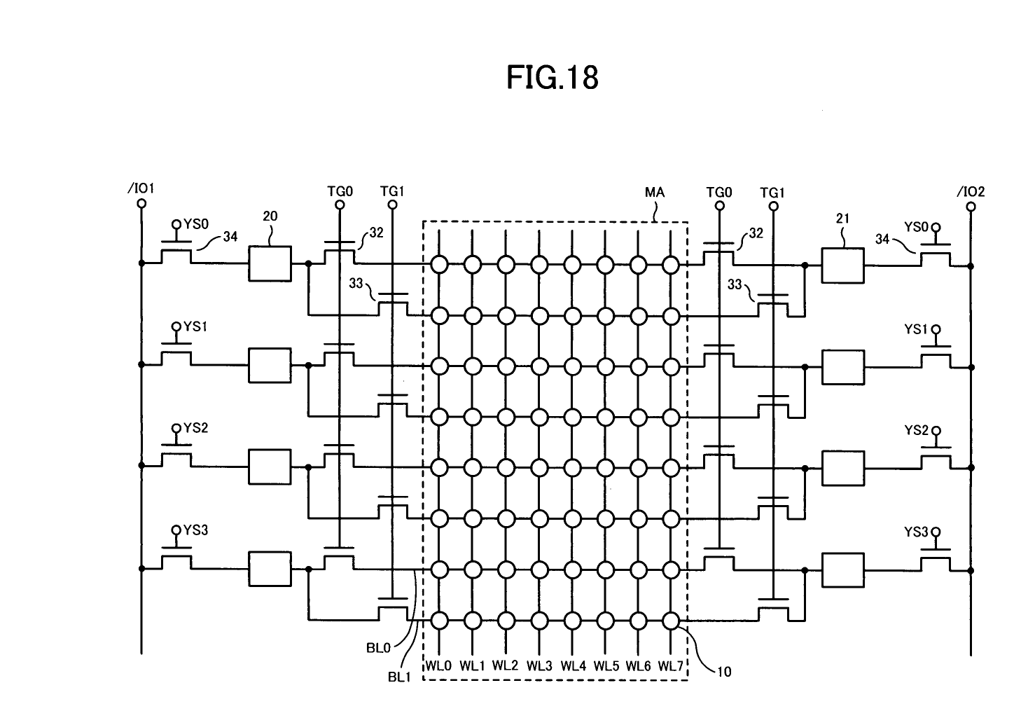

Next, FIG. 18 shows a circuit configuration of a sixth example of the memory cell array and the sense amplifier circuit in the embodiment. In the sixth example, there is provided a memory cell array MA in which the circuit configuration of the second example (FIG. 8) is used as the basic unit and arranged in an array form as in the fourth example. Meanwhile, on both side of the memory cell array MA, there are provided the switch transistors 32 and 33 controlled in response to the control signals TG0 and TG1, the sense amplifiers 20 and 21 shared by the two adjacent bit lines BL0 and BL1, and MOS transistors 34 for controlling connections between the input/output lines /IO1 and /IO2 and the sense amplifiers 20 and 21 in response to the select signals YS0 to YS3, as in the fifth example. In FIG. 18, the ternary memory cells 10 are arranged at all intersections in the memory cell array MA, which is different from FIG. 16. This is a configuration suitable for writing back data read out from the ternary memory cell 10 corresponding to the above destructive read-out, which will be described in detail later.

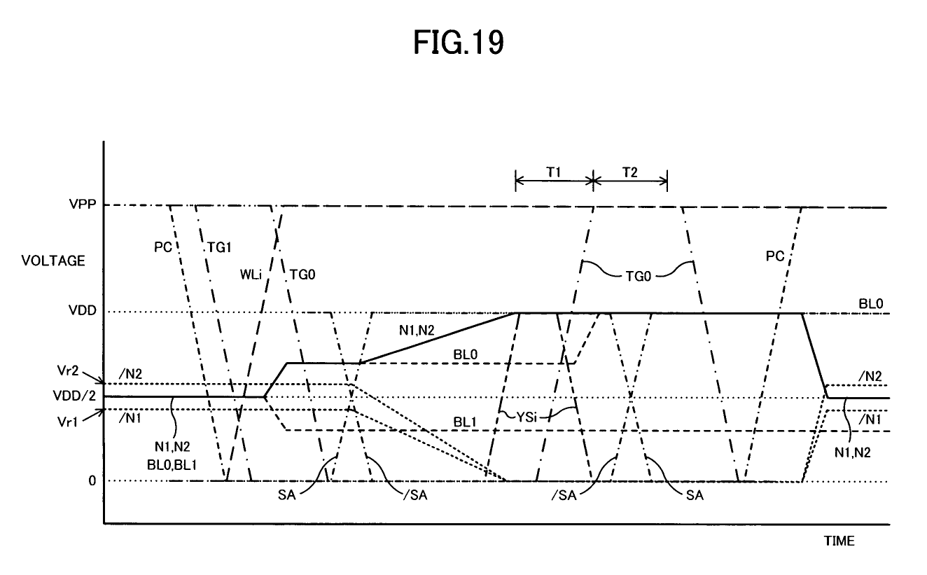

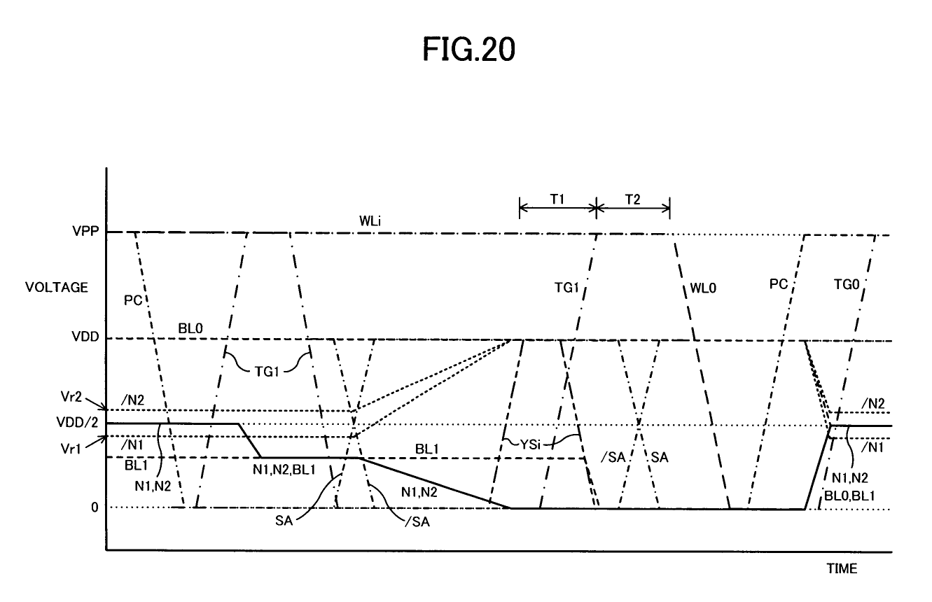

The operation when reading from the ternary memory cell 10 storing the state S2 in the sixth example will be described with reference to FIGS. 19 and 20. Many operation waveforms in the sixth example are common to those in FIG. 17, so different points will be mainly described below. FIG. 19 shows operation waveforms of the former half in the operation of the sixth example. First, in a state in which the control signal TG1 is controlled to be low and the bit line BL1 is disconnected from the sense amplifiers 20 and 21, the selected word line WLi is activated. Then, data of the ternary memory cells 10 storing the state S2 on the side of the bit line BL0 are amplified by the sense amplifiers 20 and 21 according to the same operation as in FIG. 17, and read operation during the read period T1 is performed. Thereafter, the control signal TG0 is controlled to be high, and subsequently the control signal TG0 returns to low after the data of the sense amplifiers 20 and 21 are written back to the original ternary memory cell 10. Subsequently, the precharge signal PC is controlled to be high, and both the bit lines BL0 and BL1 are maintained in a state of being disconnected from the sense amplifiers 20 and 21.

FIG. 20 shows operation waveforms in the latter half following the former half of FIG. 19 in the operation of the sixth example. This corresponds to a case of reading out the ternary memory cell 10 storing the state S0 on the bit line BL1. After the initial precharge operation is completed, the control signal TG1 is controlled to be high so that the bit line BL1 is connected to the sense amplifiers 20 and 21, and data of the ternary memory cell 10 is sent to the sense amplifiers 20 and 21 through the bit line BL1. Thereafter, the control signal TG1 is again controlled to be low so that the sense amplifiers 20 and 21 are activated. Then the nodes /N1 and /N2 are amplified to high and the nodes N1 and N2 are amplified to low. Thereafter, the precharge signal PC is controlled to be high after the read and write back operations are performed, and the control signal TG0 returns to high, as in the case of FIG. 17.

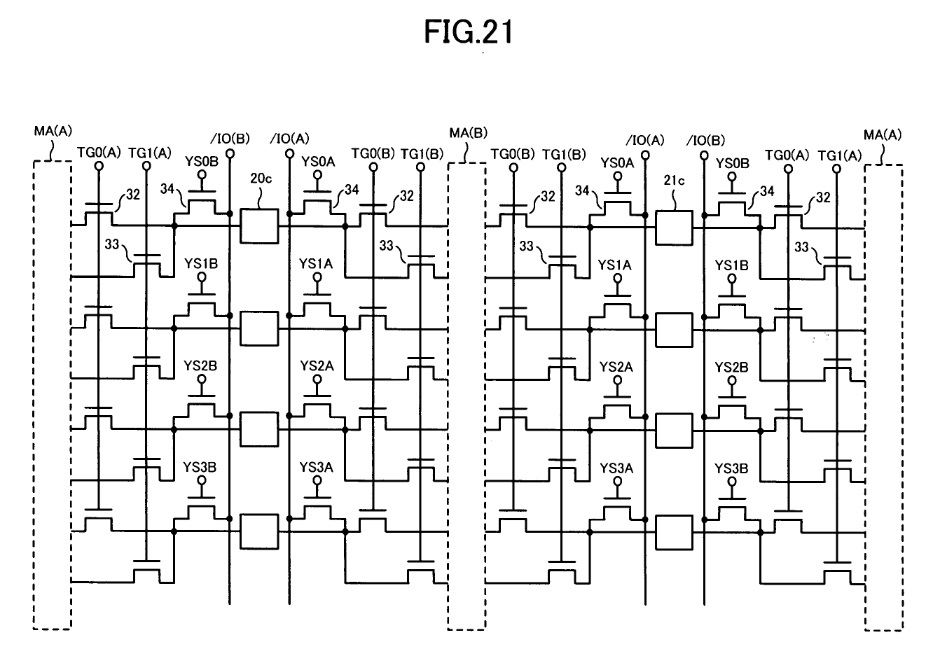

Next, FIG. 21 shows a circuit configuration of a seventh example of the memory cell array and the sense amplifier circuit in the embodiment. In the seventh example, memory cell arrays MA(A) and memory cell arrays MA(B) are alternately arranged in order to extend the memory cell array MA of the sixth example to an extending direction of the bit line BL. Each of the sense amplifiers 20c and 21c is shared by the memory cell arrays MA(A) and MA(B) on both sides. Further, the switch transistors 32, 33 and the MOS transistor 34 are arranged between the memory cell arrays MA(A), MA(B) and the sense amplifiers 20c, 21c, in the same manner as in FIG. 18. Furthermore, the control signals TG0 (A), TG1 (A), the input/output line /IO(A), the select signals YS0A to YS3A correspond to one memory cell array MA (A), while the control signals TG0 (B), TG1 (B), the input/output line /IO(B), the select signals YS0B to YS3B correspond to the other memory cell array MA(B). In addition, in the sense amplifier 20c (21c), the reference potential Vr1 (Vr2) is supplied by the same configuration as in FIG. 12.

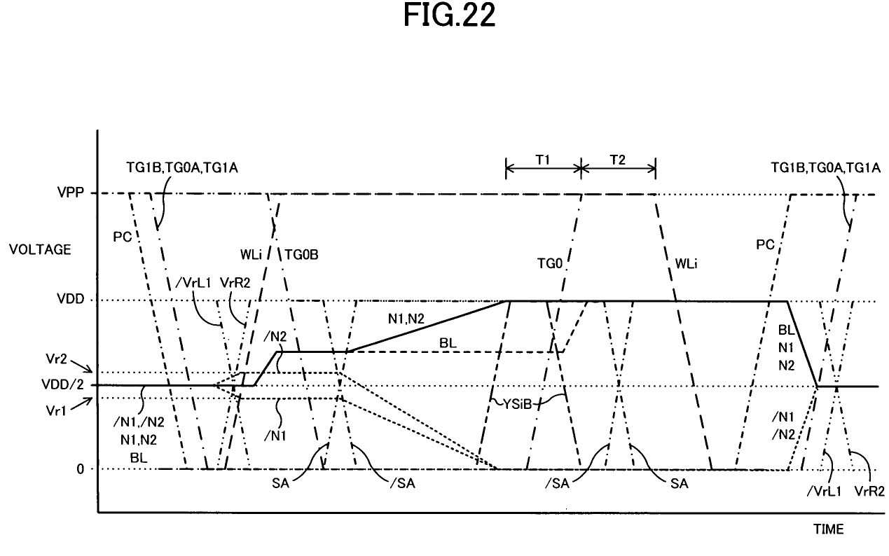

The operation in the seventh example will be described with reference to FIG. 22. FIG. 22 shows waveforms when a word line WLi included in the memory cell array MA(B) of FIG. 21 is selected and the ternary memory cell 10 storing the state S2 is read out. After the initial precharge period, control signals TG1B, TG0A and TG1A are controlled to be low, and the bit line BL connected to the selected ternary memory cell 10 is connected to the sense amplifiers 20c and 21c via the switch transistor 32, before the selected word line WLi is activated. Thereafter, the operation is almost similar to that in FIG. 13. However, after the last precharge signal PC is controlled to be high, the control signals TG1B, TG0A and TG1A return to high.

By employing the above seventh example, the adjacent memory cell arrays MA can share the sense amplifiers 20c and 21c. Therefore, the number of arranged sense amplifiers 20c and 21c can be small, and the entire chip area of the semiconductor memory device can be reduced so as to achieve the configuration advantageous for reducing cost.

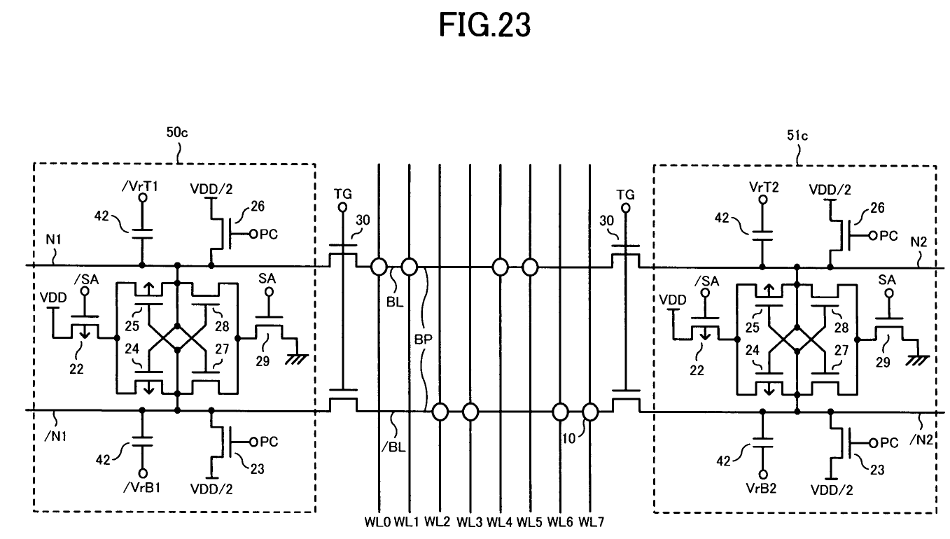

Next, FIG. 23 shows a circuit configuration of an eighth example of the memory cell array and the sense amplifier circuit in the embodiment. In the eighth example, a so-called folded bit line method is applied to the embodiment, in which a pair of bit lines BL and /BL operate to constitute a complementary pair. As shown in FIG. 23, each ternary memory cell 10 is arranged at an intersection of either of the pair of bit lines BL and /BL on each of the word lines WL0 to WL7. Sense amplifiers 50c and 51c are arranged on both sides of the pair of bit lines BL and /BL, and switch transistors 30 are also provided for controlling connections between the sense amplifiers 50c and 51c and the pair of bit lines BL and /BL in response to the control signal TG.

Each of the sense amplifiers 50c and 51c is composed of the MOS transistors 22 to 29 as in FIG. 12 and two capacitors 42, however the connection relation of the nodes N1, /N1, N2 and /N2 is different from FIG. 12. That is, among the pair of bit lines BL and /BL, one bit line BL is connected to the nodes N1 and N2 via the switch transistor 30 while the other bit line /BL is connected to the nodes /N1 and /N2 via the switch transistor 30. The reference potential applying signals /VrT1 and VrT2 are applied to opposite electrodes of the capacitors 42 on the sides of the nodes N1 and N2, and the reference potential applying signals /VrB1 and VrB2 are applied to opposite electrodes of the capacitors 42 on the sides of the nodes /N1 and /N2.

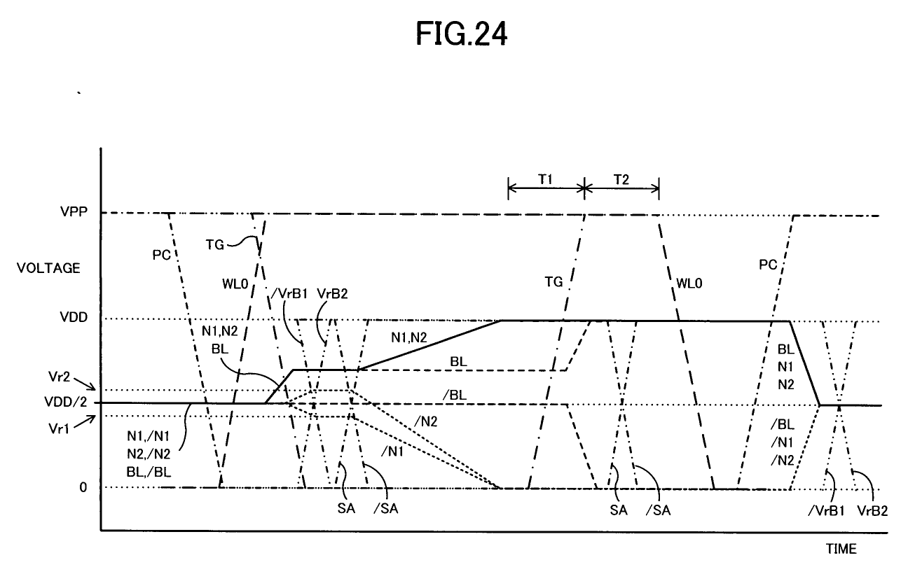

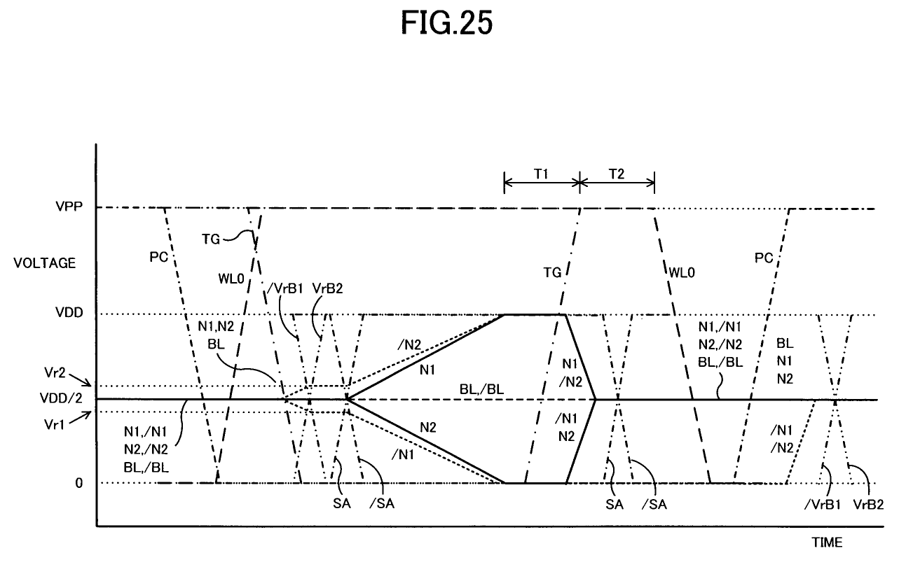

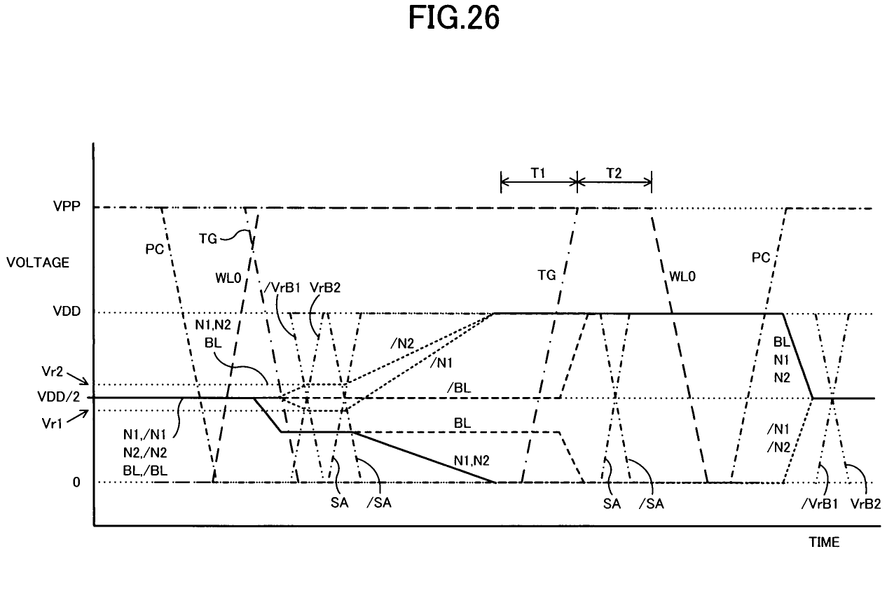

The operation in the eighth example will be described with reference to FIGS. 24 to 26, which correspond to cases in which the ternary memory cell 10 stores the state S2 (FIG. 24), the state S1 (FIG. 25) and the state S0 (FIG. 26), respectively. First, many operation waveforms in FIG. 24 are common to FIG. 9, however it is different from FIG. 9 in that the potential of bit line /BL exists and that the applying method of the reference potentials Vr1 and Vr2 is the same as in FIG. 13. The potential of the bit line BL is increased corresponding to the state S2 until the read period T1, while the bit line /BL is maintained at VDD/2. Further, the nodes N1 and N2 are amplified to high, while the nodes /N1 and /N2 are amplified to low. During the rewrite period T2, the bit line BL rises to the high potential, while the bit line /BL falls to low.

Although operation waveforms in FIGS. 25 and 26 are almost the same as in FIGS. 10 and 11 respectively, there are the above-mentioned different points. In FIG. 25, one bit line BL and the other bit line /BL are both maintained at VDD/2, and the nodes N1 and /N2 are amplified to high while the nodes /N1 and N2 are amplified to low. Further, in FIG. 26, a relation of waveforms of the bit line /BL and the nodes /N1 and /N2 to waveforms of the bit line BL and the nodes N1 and N2 is reversed relative to that in FIG. 24.

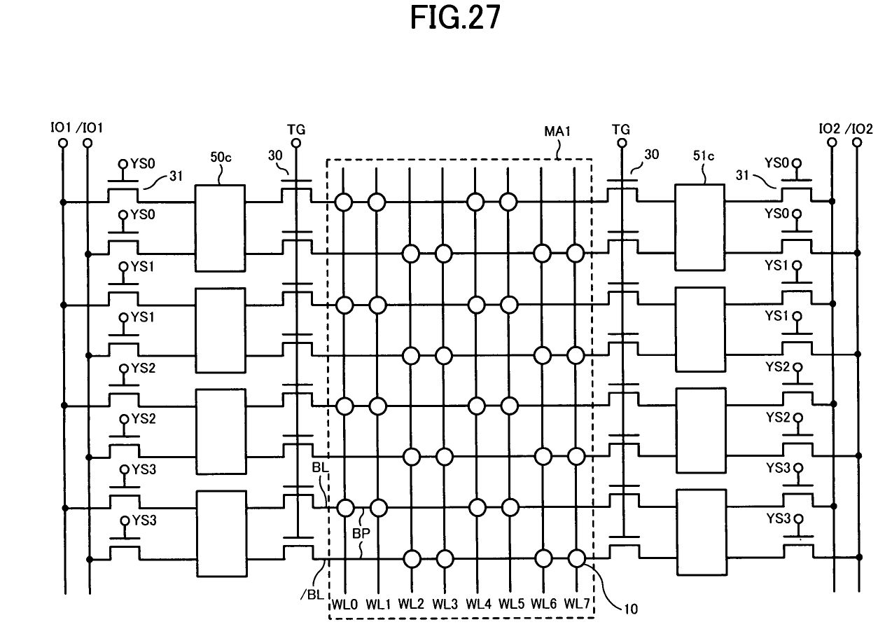

Next, FIG. 27 shows a circuit configuration of a ninth example of the memory cell array and the sense amplifier circuit in the embodiment. In FIG. 27, there is provided a memory cell array MA1 of the folded bit line method, in which many pairs of bit lines BL and /BL are arranged in parallel and the circuit configuration of the eighth example (FIG. 23) is used as the basic unit. There are also provided a large number of the switch transistors 30 of FIG. 23, the MOS transistors 31 and the sense amplifiers 50c and 51c, which are arranged in parallel. In FIG. 27, select signals YS0 to YS3 are supplied to the gate of each NMOS transistor 31, there are provided a pair of input/output lines IO1 and IO2 connected to the NMOS transistors 31 for one bit lines BL on both sides, and a pair of input/output lines /IO1 and /IO2 connected to the NMOS transistors 31 for the other bit lines /BL on both sides.

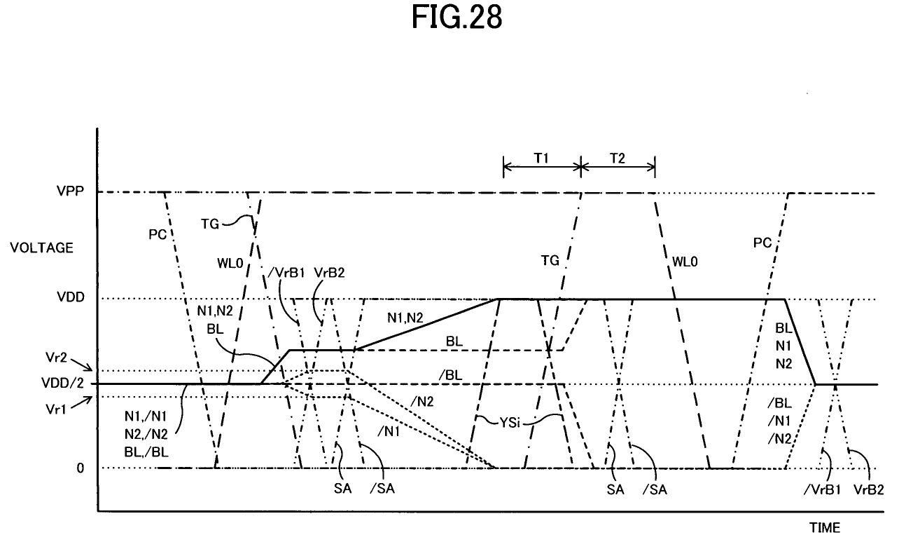

The operation when reading from the ternary memory cell 10 storing the state S2 in the ninth example will be described with reference to FIG. 28. Many operation waveforms shown in FIG. 28 are common to those in FIG. 24, however a waveform of the predetermined select signal YSi is added. That is, the nodes N1 and N2 are amplified to high and the nodes /N1 and /N2 are amplified to low, and thereafter the select signal YSi is controlled to be high. Thereby, data of the nodes N1 and N2 are read out to the input/output lines IO1 and IO2, and data of the nodes /N1 and /N2 are read out to the input/output lines /IO1 and /IO2.

By employing the above eighth and ninth examples, the ternary memory cells 10 can be arranged at half intersections in the memory cell array MA, and read-out of each pair of bit lines BL constituting the complementary pair can be performed. Therefore, a configuration advantageous for improving the sensitivity of the sense amplifiers 50c and 51c can be achieved, in addition to the fast read operation.

As described above, the present invention has been specifically described based on the embodiment, however the present invention is not limited to the above-described embodiment, and various modifications can be made without departing from the scope of the present invention. For example, the case where the molecule memory cell having the structure of FIG. 1 is used as the ternary memory cell 10 has been described, however the present invention can be applied to a case where a ternary memory cell 10 having a different principal is used if the ternary memory cell 10 can store three different states.

The present invention is not limited to the above described embodiments, and various variations and modifications may be possible without departing from the scope of the present invention.

This application is based on the Japanese Patent application No. 2007-169808 filed on Jun. 27, 2007, entire content of which is expressly incorporated by reference herein.

What is claimed is:

1. A semiconductor memory device comprising:
a plurality of memory cells each capable of storing at least three different states;
a first sense amplifier for amplifying a ternary potential read out in accordance with a state stored in a selected said memory cell based on a comparison with a first reference potential; and
a second sense amplifier for amplifying a ternary potential readout in accordance with a state stored in the selected said memory cell based on a comparison with a second reference potential,
wherein the ternary potential comprises a high potential, a medium potential and a low potential, the first reference potential is set between the low potential and the medium potential, and the second reference potential is set between the high potential and the medium potential.

2. The semiconductor memory device according to claim 1, wherein each of said memory cells is a molecule memory cell having a charge state being changed among at least three types due to oxidation-reduction of molecules.

3. The semiconductor memory device according to claim 1, wherein activation and deactivation of said first and second sense amplifiers are controlled simultaneously in a read operation of said memory cell, and data corresponding to said memory cell is read out by one amplification operation respectively.

4. The semiconductor memory device according to claim 1, further comprising a memory cell array in which said plurality of memory cells are arranged at all intersections of a plurality of word lines and a plurality of bit lines,
wherein said first and second sense amplifiers amplify the ternary potential which is read out through the bit line from the memory cell selected by activating the word line.

5. The semiconductor memory device according to claim 1, further comprising a memory cell array in which said plurality of memory cells are arranged at half intersections of a plurality of word lines and a plurality of bit lines,
wherein said first and second sense amplifiers amplify the ternary potential which is read out through the bit line connected to the memory cell selected by activating the word line.

6. The semiconductor memory device according to claim 1, further comprising a memory cell array in which said plurality of memory cells are arranged at half intersections of a plurality of word lines and a plurality of bit lines,
wherein said first and second sense amplifiers amplify the ternary potential which is read out through the bit line constituting a complementary pair from the memory cell selected by activating the word line.

7. The semiconductor memory device according to claim 1, wherein each of said first and second sense amplifiers is connected to one end of the bit line via a switch circuit controlled by a control signal.

8. The semiconductor memory device according to claim 1, wherein said first and second sense amplifiers are selectively connected to two adjacent bit lines via a first switch circuit controlled by a first control signal and a second switch circuit controlled by a second control signal.

9. The semiconductor memory device according to claim 8, wherein said first and second sense amplifiers are shared by the two adjacent bit lines.

10. The semiconductor memory device according to claim 1 wherein each of the first and second reference potentials is directly supplied to said first or second sense amplifier via a transistor.

11. The semiconductor memory device according to claim 1 wherein each of the first and second reference potentials is indirectly supplied to said first or second sense amplifier via a capacitor.

12. A read method of a semiconductor memory device having memory cells each capable of storing at least three different states, comprising the steps of:
performing a first amplification based on a comparison between a ternary potential read out in accordance with a state stored in a selected said memory cell and a first reference potential; and
performing a second amplification based on a comparison between a ternary potential read out in accordance with a state stored in a selected said memory cell and a second reference potential,
wherein the ternary potential comprises a high potential, a medium potential and a low potential, the first reference potential is set between the low potential and the medium potential, and the second reference potential is set between the high potential and the medium potential.

13. The read method according to claim 12, wherein each of said memory cells is a molecule memory cell having a charge state being changed among at least three types due to oxidation-reduction of molecules.

14. The read method according to claim 12, wherein activation and deactivation of the first and second amplifications are controlled simultaneously, and data corresponding to said memory cell is read out by one amplification operation respectively.
